(19) United States
(12) Patent Application Publication
(10) Pub. No.: US 2026/0047074 A1
(43) Pub. Date: Feb. 12, 2026

(54) SEMICONDUCTOR DEVICE

(71) Applicant: Samsung Electronics Co., Ltd., Suwon-si (KR)

(72) Inventors: Joonho Byeon, Suwon-si (KR); Sangkyu Sun, Suwon-si (KR); Jaemin Lee, Suwon-si (KR); Doyeon Kim, Suwon-si (KR); Sangmin Jeong, Suwon-si (KR); Jaybok Choi, Suwon-si (KR)

(21) Appl. No.: 19/265,016

(22) Filed: Jul. 10, 2025

(30) Foreign Application Priority Data
Aug. 7, 2024 (KR) 10-2024-0105228

(51) Int. Cl. H10B 12/00

(52) U.S. Cl. CPC H10B 12/315; H10B 12/34; H10B 12/50; H10B 12/09

(57) ABSTRACT

A semiconductor device may include a substrate including a first trench in a cell region, a second trench in a core/peripheral region, and a boundary trench in a boundary region between the cell region and the core/peripheral region, and the substrate including an active dam pattern between the boundary trench and the second trench; a first device isolation pattern filling the first trench; a second device isolation pattern filling the second trench; and a third device isolation pattern filling the boundary trench. A first sidewall of the active dam pattern corresponding to one sidewall of the boundary trench and a second sidewall of the active dam pattern corresponding to one sidewall of the second trench face to each other, and a slope of the first sidewall is different from a slope of the second sidewall with respect to a bottom surface of the substrate.

### CROSS-REFERENCE TO RELATED APPLICATION

This application claims priority under 35 U.S.C. § 119 to Korean Patent Application No. 10-2024-0105228, filed on Aug. 7, 2024, in the Korean Intellectual Property Office (KIPO), the contents of which are incorporated by reference herein in their entirety.

### BACKGROUND

Various example embodiments relate to a semiconductor device. Particularly, various example embodiments relate to active patterns and device isolation patterns in a dynamic random access memory (DRAM) device.

A substrate of a DRAM device may include a cell region in which memory cells are formed, a core/peripheral region in which core/peripheral circuits are formed, and a boundary region between the cell region and the core/peripheral region. Device isolation patterns may be arranged on the substrate of the cell region, the core/peripheral region, and the boundary region. Active patterns may be disposed between the isolation patterns.

### SUMMARY

Various example embodiments provide a semiconductor device having excellent operating characteristics.

According to some example embodiments, there is provided a semiconductor device. The semiconductor device may include a substrate including a first trench in a cell region, a second trench in a core/peripheral region, and a boundary trench in a boundary region between the cell region and the core/peripheral region, and the substrate including an active dam pattern between the boundary trench and the second trench; a first device isolation pattern filling the first trench; a second device isolation pattern filling the second trench; and a third device isolation pattern filling the boundary trench. A first sidewall of the active dam pattern corresponding to one sidewall of the boundary trench and a second sidewall of the active dam pattern corresponding to one sidewall of the second trench face to each other, and a slope of the first sidewall is different from a slope of the second sidewall with respect to a bottom surface of the substrate.

According to some example embodiments, there is provided a semiconductor device. The semiconductor device may include a substrate including a first trench and a first active pattern in a cell region, a second trench and a second active pattern in a core/peripheral region, and a boundary trench and an active dam pattern in a boundary region between the cell region and the core/peripheral region; a first device isolation pattern filling the first trench; a second device isolation pattern filling the second trench; and a third device isolation pattern filling the boundary trench. The active dam pattern may be positioned between the boundary trench and the second trench. A first sidewall of the active dam pattern and a second sidewall facing the first sidewall of the active dam pattern may be asymmetrical to each other. The second trench may have a depth greater than a depth of the boundary trench.

According to some example embodiments, there is provided a semiconductor device. The semiconductor device may include a substrate including a first trench and a first active pattern in a cell region, a second trench and a second active pattern in a core/peripheral region, and a boundary trench and an active dam pattern in a boundary region between the cell region and the core/peripheral region; a first device isolation pattern filling the first trench; a second device isolation pattern filling the second trench; a third device isolation pattern filling the boundary trench; a first gate structure buried in the substrate of the cell region, the first gate structure extending in a first direction; a bit line structure on the substrate of the cell region; a capacitor on the substrate of the cell region; a core/peripheral transistor on the second active pattern in the substrate of the core/peripheral region. The first trench may have a first depth, the second trench has a second depth, and the boundary trench has a third depth. A difference between the second depth and the third depth may be greater than a difference between the first depth and the third depth.

In a method of manufacturing the semiconductor device according to example embodiments, an etching process for forming the second active pattern and an etching process for forming the first active pattern and the active dam pattern may be performed separately. Therefore, the first active pattern, the active dam pattern, and the second active pattern may be formed on the substrate. Accordingly, the semiconductor device may include the first active pattern, the active dam pattern, and the second active pattern having desired architectures.

### BRIEF DESCRIPTION OF THE DRAWINGS

Various example embodiments will be more clearly understood from the following detailed description taken in conjunction with the accompanying drawings. FIGS. 1 to 29 represent various non-limiting, example embodiments as described herein.

FIG. 1 is a cross-sectional view illustrating active patterns and device isolation patterns in a semiconductor device according to example embodiments;

FIGS. 2A and 2B are cross-sectional views illustrating the active patterns in FIG. 1, respectively;

FIG. 3 is a plan view illustrating the active patterns and the device isolation patterns in the semiconductor device according to example embodiments;

FIGS. 4 to 17 are cross-sectional views and plan views illustrating a method of forming active patterns in a semiconductor device according to example embodiments;

FIGS. 18 and 19 are cross-sectional views illustrating semiconductor devices according to example embodiments;

FIG. 20 is a plan view illustrating semiconductor devices according to example embodiments; and

FIGS. 21 to 29 are cross-sectional views and plan views illustrating a method of manufacturing a semiconductor device according to example embodiments.

### DETAILED DESCRIPTION

Hereinafter, various example embodiments will be described in detail with reference to the accompanying drawings. In the following description, directions parallel to a surface of a substrate and perpendicular to each other are referred to as a first direction and a second direction, respectively. In addition, a direction parallel to an upper surface of the substrate and oblique to the first direction (i.e., an oblique direction) is referred to as a third direction.

Like reference characters refer to like elements throughout. Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise.

The term “buried” may refer to structures, patterns, and/or layers that are formed at least partially below a top surface of another structure, pattern, and/or layer. In some embodiments, when a first structure, pattern, and/or layer is “buried” in a second structure, pattern, and/or layer, the second structure, pattern, and/or layer may surround at least a portion of the first structure, pattern, and/or layer. For example, a first structure, pattern, and/or layer first may be considered to be buried when it is at least partially embedded in a second structure, pattern, and/or layer.

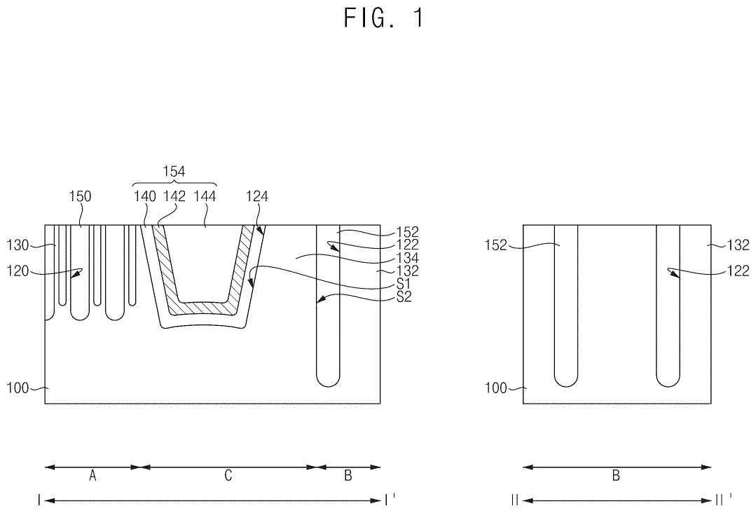

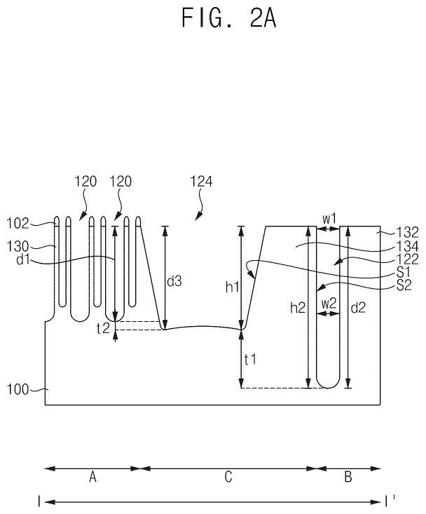

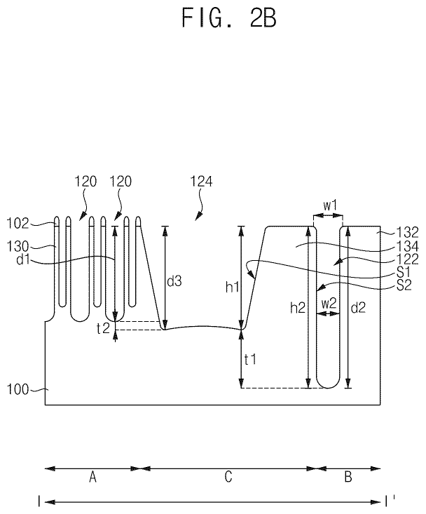

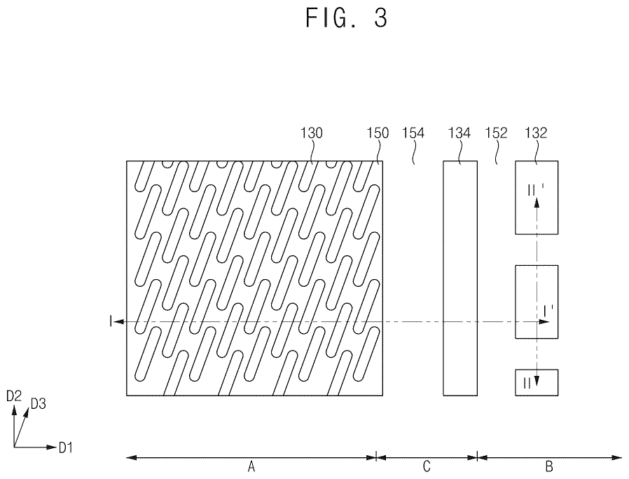

FIG. 1 is a cross-sectional view illustrating active patterns and device isolation patterns in a semiconductor device according to example embodiments. FIGS. 2A and 2B are cross-sectional views illustrating the active patterns in FIG. 1, respectively. FIG. 3 is a plan view illustrating the active patterns and the device isolation patterns in the semiconductor device according to example embodiments.

FIG. 1 includes cross-sectional views taken along lines I-I′ and II-II′ of FIG. 3.

Referring to FIGS. 1 to 3, the semiconductor device may be formed on a substrate 100. The substrate 100 may include a cell region A, a core/peripheral region B, and a boundary region C disposed between the cell region A and the core/peripheral region B.

The substrate 100 may include a single crystalline semiconductor material. The substrate 100 may include a semiconductor material such as silicon, germanium, silicon-germanium, etc. In example embodiments, the substrate 100 may be single crystal silicon.

The core/peripheral region B may be spaced apart from an edge of the cell region A, and may surround the cell region A. The boundary region C may be a region to distinguish the cell region A and the core/peripheral region B. The boundary region C may surround the cell region A.

Trenches and device isolation patterns filling the trenches may be on the substrate 100. The device isolation pattern may include an insulation material. A region where the device isolation pattern is formed may serve as a device isolation region. A protruding portion of the substrate 100 between the trenches may serve as an active pattern. The active pattern may be defined by the device isolation pattern. An upper surface of the active pattern may serve as an active region for forming circuit devices.

First trenches 120 and first active patterns 130 may be arranged on the substrate 100 of the cell region A. The first active pattern 130 may correspond to a region of the substrate 100 between the first trenches 120. A first device isolation pattern 150 may fill the first trench 120. The first device isolation pattern 150 may cover sidewalls of the first active pattern 130. In example embodiments, an upper surface of the first device isolation pattern 150 may be coplanar with upper surfaces of the first active patterns 130. The first active pattern 130 may be a region of the substrate 100 of the cell region A where the first device isolation pattern 150 is not formed. An upper surface of the first active pattern 130 may serve as the active region.

Each of the first active patterns 130 may extend in the third direction D3. The third direction D3 may be a longitudinal direction of the first active pattern 130, e.g., a long-axis direction. The first active patterns 130 may be regularly arranged in the first and second directions D1 and D2 to be spaced apart from each other. In addition, the first active patterns 130 may be spaced apart from one another in the third direction D3.

Second trenches 122 and second active patterns 132 may be arranged on the substrate 100 of core/peripheral region B. The second active pattern 132 may correspond to a region of the substrate 100 between the second trenches 122. A second device isolation pattern 152 may fill the second trench 122. In example embodiments, an upper surface of the second active pattern 132 may be coplanar with upper surfaces of the second device isolation patterns 152. The second active pattern 132 may be a region of the substrate 100 of the core/peripheral region B where the second device isolation pattern 152 is not formed. An upper surface of the second active pattern 132 may serve as the active region.

A boundary trench 124 and an active dam pattern 134 may be disposed on the substrate 100 of the boundary region C. A third device isolation pattern 154 may fill the boundary trench 124. In example embodiments, an upper surface of the third device isolation pattern 154 may be coplanar with an upper surface of the active dam pattern 134. The active dam pattern 134 may be disposed within the boundary region C, and may be arranged outside the boundary trench 124.

The boundary trench 124 may be adjacent to an edge of the cell region A. In addition, the active dam pattern 134 may be adjacent to an edge of the core/peripheral region B. The boundary trench 124 may be positioned between the first active pattern 130 and the active dam pattern 134. The active dam pattern 134 may be positioned between the boundary trench 124 and the second trench 122.

The first trench 120, the second trench 122, and the boundary trench 124 may have target inner widths and target depths, respectively. The first trench 120, the second trench 122, and the boundary trench 124 may have different inner widths to each other. At least one of the first trench 120, the second trench 122, and the boundary trench 124 may have a different depth. In example embodiments, the first trench 120, the second trench 122, and the boundary trench 124 may have different depths from one another.

The first to third device isolation patterns 150, 152, and 154 may have different widths to each other. At least one of the first to third device isolation patterns 150, 152, and 154 may have a different vertical height. A depth of the trench may be defined as a vertical distance from a top to a bottom of the trench. A height of the device isolation pattern may be defined as a vertical distance from a top to a bottom of the device isolation pattern.

The boundary trench 124 may have a sufficient width for dividing the cell region A and the core/peripheral region B and insulating the cell region A and the core/peripheral region B from each other. Therefore, the inner width of the boundary trench 124 may be greater than the inner width of each of the first and second trenches 120 and 122. In addition, as memory cells may be densely formed on the cell region A, the inner width of the first trench 120 may be less than the inner width of the second trench 122.

The first trench 120 may have a first depth d1, the second trench 122 may have a second depth d2, and the boundary trench 124 may have a third depth d3.

The second depth d2 may be a sufficient depth for isolating between core/peripheral circuits. The second trench 122 may be formed by a separate etching process for forming the second trench 122, so that the second depth d2 may be controlled. The second depth d2 may be greater than each of the first depth d1 and the third depth d3. A bottom of the second trench 122 may be lower than each of a bottom of the first trench 120 and a bottom of the boundary trench 124.

The first trench 120 may have the first depth d1 targeted for device isolation of the memory cells, and the first depth d1 may be less than the second depth d2. The first trench 120 and the boundary trench 124 may be formed by the same etching process, so that a difference between the first depth d1 and the third depth d3 may not be great.

In example embodiments, the inner width of the boundary trench 124 may be greater than the inner width of the first trench 120, and thus the third depth d3 may be greater than the first depth d1. In some example embodiments, the third depth d3 may be the same as or similar to the first depth d1. A difference t1 between the second depth d2 and the third depth d3 may be greater than the difference t2 between the first depth d1 and the third depth d3. In example embodiments, the second depth d2 may be greater than the third depth d3 by at least 500 Å.

In this way, the second trench 122 may have the second depth d2 sufficient for the device isolation of the core/peripheral circuits without considering the inner widths and the depths of the first trench 120 and the boundary trench 124. In addition, the first trench 120 may have the first depth d1 targeted for the device isolation of the memory cells without considering the inner width and the depth of the second trench 122.

A height of the second device isolation pattern 152 may be higher than each of heights of the first device isolation pattern 150 and the third device isolation pattern 154.

A sidewall of the first trench 120 may extend nearly or substantially in a vertical direction with respect to a bottom surface of the substrate 100, and a bottom of the first trench 120 may have a shape that is rounded downward.

A sidewall of the boundary trench 124 may have a slope that is not perpendicular to the bottom surface of the substrate 100. The sidewall of the boundary trench 124 may have a slope so that the inner width of the boundary trench 124 may decrease from a top to a bottom of the boundary trench 124. For example, the sidewall of the boundary trench 124 may have an inclined slope, which is inclined with respect to the bottom surface of the substrate 100. In example embodiments, the bottom of the boundary trench 124 may have a shape that is rounded convexly upward. A center portion of the bottom of the boundary trench 124 may be higher than an edge portion of the bottom of the boundary trench 124.

A sidewall of the second trench 122 may extend nearly or substantially vertical direction with respect to the bottom surface of the substrate 100, and a bottom of the second trench 122 may have a shape that is rounded downward. In this way, the bottom of the second trench 122 and the bottom of the boundary trench 124 may have different shapes.

For example, as shown in FIG. 2A, the inner widths of the second trench 122 may be the same at each of positions in the vertical direction. For example, at each pair of positions at the same level on either side of the second trench, the inner width of the second trench 122 may be the same.

For another example, as shown in FIG. 2B, an uppermost edge of the second trench 122 may have a rounded shape, and thus an inner width of the uppermost portion of the second trench 122 may be slightly greater than an inner width of a portion below the uppermost portion of the second trench 122. However, a depth of the rounded portion of the uppermost portion of the second trench 122 are very small, and the inner width of the uppermost portion of the second trench 122 may be limitedly expanded so as not to affect a characteristic of the semiconductor device.

The second trench 122 may have almost or substantially no difference between the inner width W1 at the uppermost portion and the inner width W2 at a middle portion in the vertical direction. In example embodiments, the difference between the inner width W1 at the uppermost portion and the inner width W2 at the middle portion in the vertical direction of the second trench 122 may be less than 5% of the inner width W1 at the uppermost portion of the second trench 122.

When the upper width of the second trench 122 is excessively expanded compared to the lower width, an area of an upper surface of the second active pattern 132 may be decreased. Thus, it is difficult for the second active pattern 132 to have a target upper surface area. However, in example embodiments, the upper width of the second trench 122 may be hardly expanded compared to the lower width of the second trench 122, so that the area of the upper surface of the second active pattern 132 may not be decreased. Therefore, the second active pattern 132 may have a sufficient target upper surface area.

The sidewall of the first trench 120 may have a first slope, the sidewall of the second trench 122 may have a second slope, and the sidewall of the boundary trench 124 may have a third slope. The first slope and the third slope may be different from each other. The second slope and the third slope may be different from each other.

The active dam pattern 134 may have both sidewalls facing each other defined by one sidewall of the boundary trench 124 and one sidewall of the second trench 122. A first sidewall S1 of the active dam pattern 134 may correspond to the one sidewall of the boundary trench 124, and a second sidewall S2 facing the first sidewall S1 of the active dam pattern 134 may correspond to the one sidewall of the second trench 122.

The first sidewall S1 and the second sidewall S2 of the active dam pattern 134 may be asymmetrical to each other. The first sidewall S1 of the active dam pattern 134 may have the third slope, and the second sidewall S2 of the active dam pattern 134 may have the second slope. Thus, facing sidewalls of the active dam pattern 134 may have different slopes with respect to a bottom surface of the substrate 100. The second slope of the active dam pattern 134 may be steeper than the third slope. A slope angle of the second sidewall S2 of the active dam pattern 134 may be greater than a slope angle of the first sidewall S1. In example embodiments, the slope of the second sidewall S2 of the active dam pattern 134 may be substantially vertical slope.

A height h1 of the first sidewall S1 of the active dam pattern 134 may be different from a height h2 of the second sidewall S2 of the active dam pattern 134. A height of the sidewall may be a vertical distance from a lowest portion to a highest portion of the sidewall. The height h1 of the first sidewall S1 of the active dam pattern 134 may be lower than the height h2 of the second sidewall S2 of the active dam pattern 134.

In example embodiments, an upper surface of the active dam pattern 134 may be damaged by etching processes. However, an actual operating circuit may not be disposed on the upper surface of the active dam pattern 134, so that the damages of the upper surface of the active dam pattern 134 may not affect the semiconductor device. In some example embodiments, the upper surface of the active dam pattern 134 may not be damaged by etching processes.

An etching process for forming the second sidewall S2 of the active dam pattern 134 and the second trench 122, and an etching process for forming the first sidewall S1 of the active dam pattern 134 and the boundary trench 124 may not be performed simultaneously, but may be performed separately. Accordingly, as described above, the first sidewall S1 and the second sidewall S2 of the active dam pattern 134 may have different angles of incline, and may have different heights.

The first to third device isolation patterns 150, 152, and 154 may include an insulation material. At least one of the first to third device isolation patterns 150, 152, and 154 may have a different stacked structure. In example embodiments, the first and second device isolation patterns 150, 152 may include a first insulation layer pattern. The third device isolation pattern 154 may include the first insulation layer pattern 140, a second insulation layer pattern 142, and a third insulation layer pattern 144. The first and third insulation layer patterns 140, 144 may be formed of or include, e.g., silicon oxide, and the second insulation layer pattern 142 may be formed of or include, e.g., silicon nitride. However, the stacked structure of the insulation layer patterns included in the first to third device isolation patterns 150, 152, and 154 may not be limited thereto.

As described above, first to third active patterns 130, 132, 134 having desired architecture and device isolation patterns 150, 152, and 154 having desired architecture may be disposed on the cell region A, the core/peripheral region B, and the boundary region C of the substrate 100. Particularly in the core/peripheral region B, the upper inner width of the second trench 122 may not be expanded, and the sidewall of the second trench 122 may have a vertical slope. Therefore, the second active pattern 132 in the core/peripheral region B may have a sufficient upper surface area.

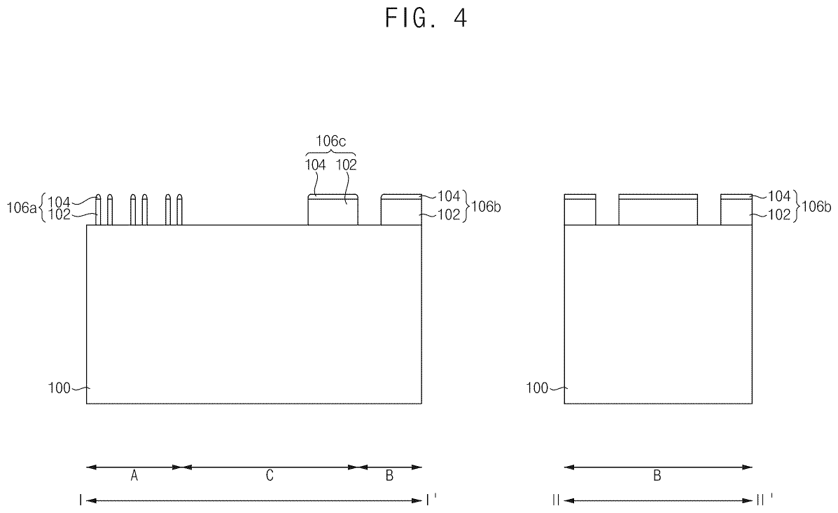

FIGS. 4 to 17 are cross-sectional views and plan views illustrating a method of forming active patterns in a semiconductor device according to example embodiments.

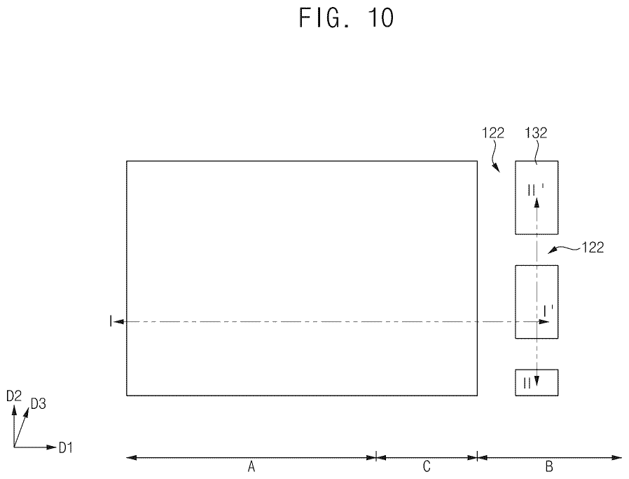

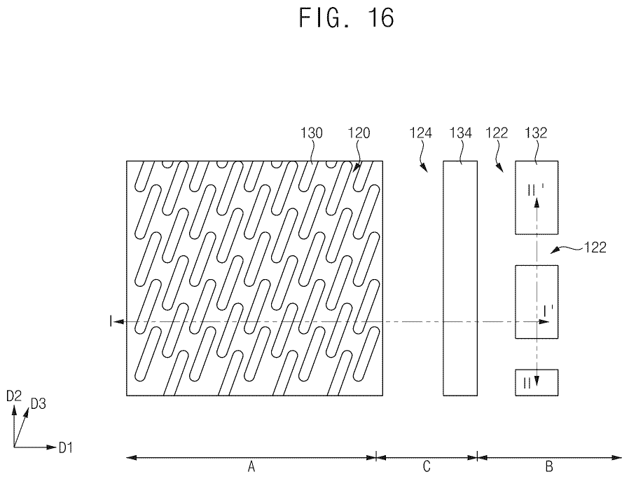

FIGS. 4 to 9, 11 to 15, and 17 are cross-sectional views, and FIGS. 10 and 16 are plan views. Each of cross-sectional views includes cross-sectional views cut along I-I′ and II-II′ of the plan view.

Referring to FIG. 4, a substrate 100 including a cell region A, a core/peripheral region B, and a boundary region C between the memory region A and the core/peripheral region B may be provided.

Mask pattern structures 106a, 106b, and 106c for forming trenches may be formed on the substrate 100. The mask pattern structures 106a, 106b, and 106c are referred to as a first mask pattern structure 106a, a second mask pattern structure 106b, and a third mask pattern structure 106c depending on their positions on the substrate 100. The first mask pattern structure 106a may be disposed on the substrate 100 of the cell region A. The second mask pattern structure 106b may be disposed on the substrate 100 of the core/peripheral region B. The third mask pattern structure 106c may be disposed on the substrate 100 of the boundary region C.

The first mask pattern structure 106a may cover a region of the substrate 100 of the cell region A where a first active pattern 130 (refer to FIG. 1) is to be formed. In the cell region A, an exposed portion between the first mask pattern structures 106a may correspond to a region where a first trench 120 (refer to FIG. 1) is to be formed. The first mask pattern structure 106a may have a first width, and a space between the first mask pattern structures 106a may have a first spacing.

The second mask pattern structure 106b may cover a region of the substrate 100 of the core/peripheral region B where a second active pattern 132 (refer to FIG. 1) is to be formed. In the core/peripheral region B, an exposed portion where the second mask pattern structure 106b is not formed may be a region where a second trench 122 (refer to FIG. 1) is to be formed. The second mask pattern structure 106b may have a second width, and a space between the second mask pattern structures 106b may have a second spacing. The second width may be greater than the first width. The second spacing may be greater than the first spacing.

The third mask pattern structure 106c may cover a region of the substrate 100 of the boundary region C where an active dam pattern 134 (refer to FIG. 1) is to be formed. In the boundary region C, an exposed portion where the third mask pattern structure 106c is not formed may be a region where a boundary trench 124 (refer to FIG. 1) is to be formed. The boundary trench 124 and the active dam pattern 134 may be disposed on the substrate 100 of the boundary region C. The boundary trench 124 may be adjacent to an edge of the cell region A. In addition, the active dam pattern 134 may be adjacent to an edge of the core/peripheral region B. In the boundary region C, an exposed portion where the third mask pattern structure 106c is not formed may have a third spacing. The third spacing may be greater than the second spacing. The third mask pattern structure 106c may have a third width, and the third width may be at least greater than the first width.

Each of the first to third mask pattern structures 106a, 106b, and 106c may have a structure in which at least two layer patterns are stacked. At least one layer pattern included in each of the first to third mask pattern structures 106a, 106b, and 106c may include a material having a high etching selectivity with respect to the substrate 100. In example embodiments, each of the first to third mask pattern structures 106a, 106b, and 106c may include a first layer pattern and a second layer pattern. The second layer pattern may include a material having a high etching selectivity with respect to the first layer pattern. The first layer pattern may serve as a main etching mask for forming trenches in a subsequent process. Therefore, a thickness of the first layer pattern may be greater than a thickness of the second layer pattern. For example, each of the first to third mask pattern structures 106a, 106b, and 106c may have a structure in which a silicon oxide layer pattern 102 and a polysilicon pattern 104 are stacked.

In example embodiments, the first to third mask pattern structures 106a, 106b, and 106c may be formed by a quadruple patterning technique QPT process or a double patterning technique DPT process.

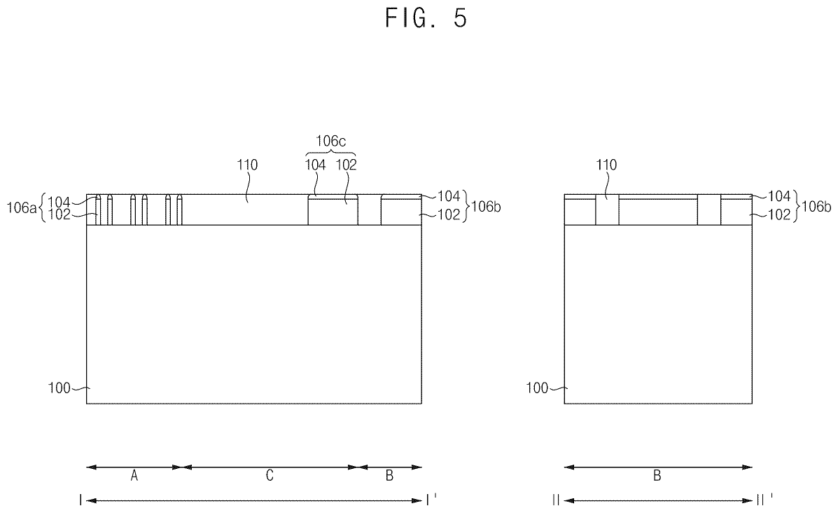

Referring to FIG. 5, a first mask layer may be formed on the first to third mask pattern structures 106a, 106b, and 106c and the substrate 100 to fill the spaces between the first to third mask pattern structures 106a, 106b, and 106c. Thereafter, the first mask layer may be planarized until upper surfaces of the first to third mask pattern structures 106a, 106b, and 106c are exposed to form a first mask pattern 110. The first mask pattern 110 may fill the spaces between the first to third mask pattern structures 106a, 106b, and 106c.

The first mask pattern 110 may include a material that can be removed by ashing and stripping processes. The first mask pattern 110 may include, e.g., a spin-on hard mask (SOH) material.

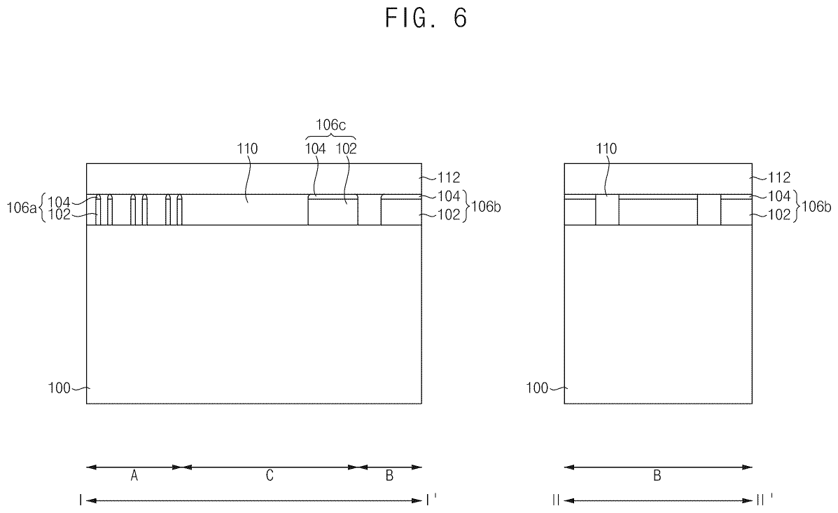

Referring to FIG. 6, a second mask layer 112 may be formed on upper surfaces of the first mask pattern 110 and the polysilicon pattern 104. The second mask layer 112 may include, e.g., silicon oxide. The second mask layer 112 may be formed by, e.g., an atomic layer deposition process.

The second mask layer 112 may be used as an etching mask for preventing of etching of the substrate 100 of the cell region A and the boundary region C in a subsequent etching process of the substrate 100 for forming the second trench 122. The second mask layer 112 may be formed to a sufficient thickness so that the second mask layer 112 may not be completely removed until the etching process for forming the second trench 122 is completed. Therefore, when the substrate 100 is etched by a target thickness in the subsequent etching process for forming the second trench 122, the second mask layer 112 may remain on the cell region A and the boundary region C to a certain thickness.

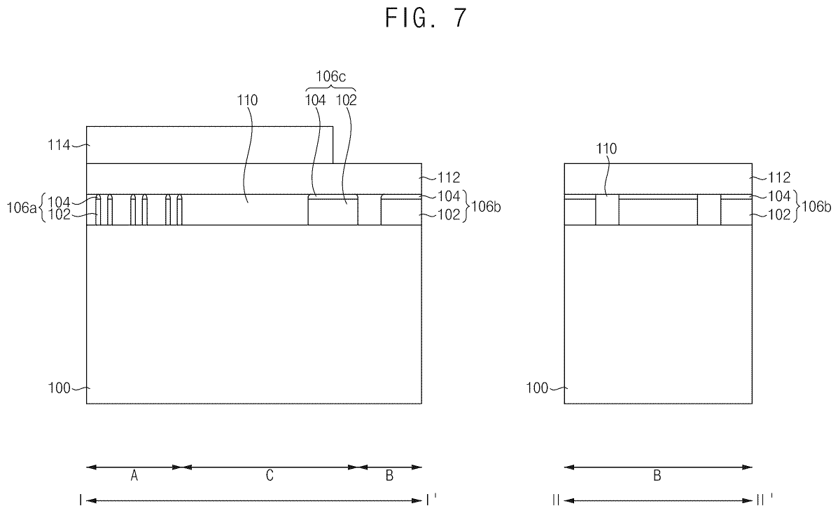

Referring to FIG. 7, a first photoresist layer may be formed on the second mask layer 112. The first photoresist layer may be patterned by a photo process to form a first photoresist pattern 114.

The first photoresist pattern 114 may cover the second mask layer 112 on the cell region A and the boundary region C. The first photoresist pattern 114 may not be formed on the second mask layer 112 of the core/peripheral region B.

In example embodiments, as shown in FIG. 7, a portion of the boundary region C adjacent to the core/peripheral region B may be exposed by the first photoresist pattern 114.

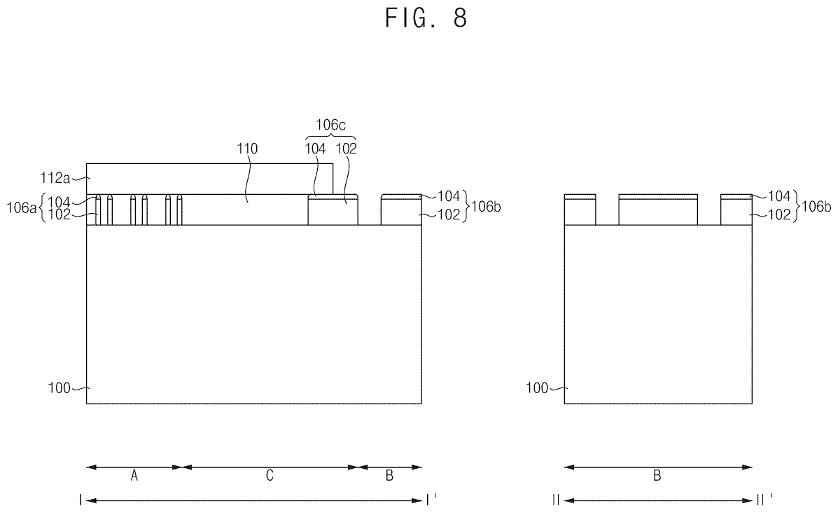

Referring to FIG. 8, the second mask layer 112 may be etched using the first photoresist pattern 114 as an etching mask to form a second mask pattern 112a. The second mask pattern 112a may cover the first and third mask pattern structures 106a and 106c and the first mask pattern 110 on the cell region A and the boundary region C. The second mask pattern 112a may expose the second mask pattern structure 106b and the first mask pattern 110 on the core/peripheral region B.

In example embodiments, as shown in FIG. 7, a portion of the third mask pattern structure 106c on the boundary region C adjacent to the core/peripheral region B may be exposed by the second mask pattern 112a.

In example embodiments, in the etching process, the polysilicon pattern 104, which is the uppermost pattern of each of the second and third mask pattern structures 106b and 106c, may serve as an etching stop layer.

Thereafter, the first photoresist pattern 114 and the first mask pattern 110 exposed by the second mask pattern 112a may be removed. The removing process may include an ashing process and a stripping process. Therefore, the first mask pattern 110 on the core/peripheral region B may be removed. In the core/peripheral region B, the first mask pattern 110 may not fill a space between the second mask pattern structures 106b, and thus the space may be between the second mask pattern structures 106b. On the core/peripheral region B, a region of the substrate 100 for forming the second trench 122 may be exposed between the second mask pattern structures 106b.

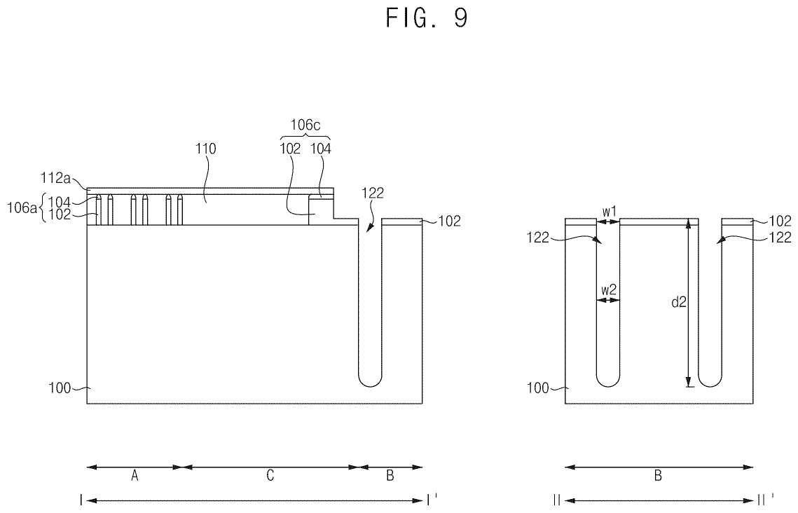

Referring to FIGS. 9 and 10, an exposed region of the substrate 100 of the core/peripheral region B may be anisotropically etched using the second mask pattern 112a and a portion of the third mask pattern structure 106c on the cell region A and the boundary region C and the second mask pattern structure 106b on the core/peripheral region B as an etching mask to form the second trench 122. A region of the substrate 100 of the core/peripheral region B in which the second trench 122 is not formed may serve as a second active pattern 132.

When the etching process (i.e., a first etching process) is performed, the second mask pattern 112a, a portion of the third mask pattern structure 106c, and the second mask pattern structure 106b used as the etching mask may not be completely removed but may be removed by a certain thickness. Even after the first etching process, at least the third mask pattern structure 106c and the second mask pattern structure 106b may remain by a certain thickness on the boundary region C and the core/peripheral region B. Even after the first etching process, at least the second mask pattern 112a may remain to a certain thickness on the cell region A.

By performing the first etching process, only the second trench 122 may be formed, and the first and third trenches may not be formed on the cell region A and the boundary region C. Therefore, the first etching process may be freely controlled so that desired second trench 122 may be formed without considering the first and third trenches on the cell region A and the boundary region C.

The second trench 122 may have a sufficient depth for an electrical isolation of the core/peripheral circuits. The second trench 122 may have a second depth d2.

A sidewall of the second trench 122 may extend nearly or substantially in a vertical direction with respect to a bottom of the substrate 100, and may not have an oblique slope. The sidewall of the second trench 122 may have a second slope. A bottom of the second trench 122 may have a shape that is rounded downward.

The first etching process may be controlled so that the second trench 122 may have almost or substantially no difference between inner widths depending on each of positions in the vertical direction.

In example embodiments, the second trench 122 may have almost or substantially the same inner widths at each of positions in the vertical direction.

In some example embodiments, an uppermost edge of the second trench 122 may have a rounded shape, and a depth of the uppermost portion of the second trench 122 having the rounded portion may be very small. Accordingly, an inner width of the uppermost portion of the second trench 122 may be slightly greater than an inner width of a portion under the uppermost portion of the second trench 122. However, in the first etching process, the inner width of the uppermost portion of the second trench 122 may not be excessively expanded compared to the inner width of the portion under the uppermost portion of the second trench 122, and may be limitedly expanded so as not to affect a characteristic of the semiconductor device.

In example embodiments, in the second trench 122, a difference between the inner width W1 at the uppermost portion and the inner width W2 at a middle portion in the vertical direction may be less than about 5% of the inner width W1 at the uppermost portion.

The inner widths of the second trench 122 may be substantially and almost the same at each of positions in the vertical direction, and an upper inner width of the second trench 122 may not be greatly expanded compared to a lower inner width of the second trench 122. Therefore, the second active pattern 132 may have a sufficient target upper surface area.

In example embodiments, during the first etching process, a region of the substrate 100 where the active dam pattern is to be formed may be damaged. In this case, a portion of the upper surface of the active dam pattern subsequently formed may be damaged by the first etching process.

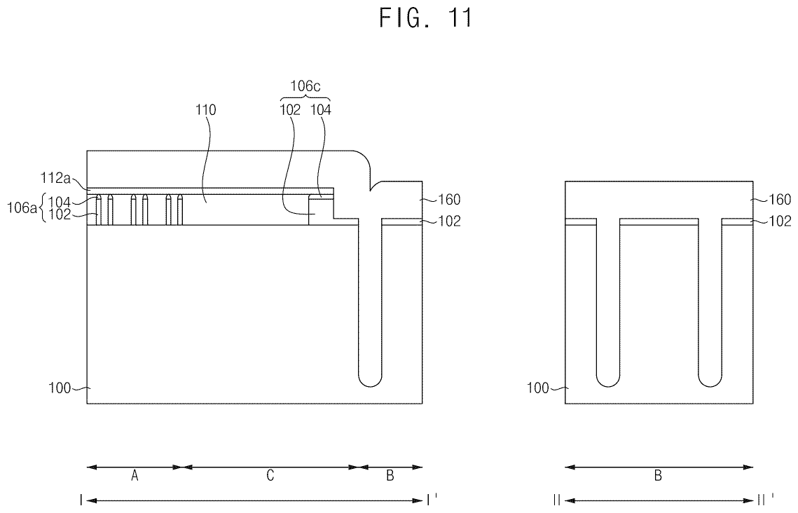

Referring to FIG. 11, a protective layer 160 may be formed on the second mask pattern 112a, the second mask pattern structure 106b, the third mask pattern structure 106c, and the second trench 122 to completely fill the second trench 122. The protective layer 160 may be formed on the cell region A, the boundary region C, and the core/peripheral region B.

The protective layer 160 may protect the substrate 100 and the second trench 122 of the core/peripheral region B, during a subsequent etching process for forming the first trench 120 and the boundary trench 124 on the substrate 100 of the cell region A and the boundary region C. Therefore, the protective layer 160 may include a material having a high etching selectivity with respect to the substrate 100, in the subsequent etching process. The protective layer 160 may be formed of or include, e.g., silicon oxide. The protective layer 160 may be formed by, e.g., a chemical vapor deposition process or an atomic layer deposition process.

The protective layer 160 on the substrate 100 of the core/peripheral region B may be formed to have a sufficient thickness so that the protective layer 160 may remain to a certain thickness even after the subsequent etching process for forming the first trench 120 and the boundary trench 124.

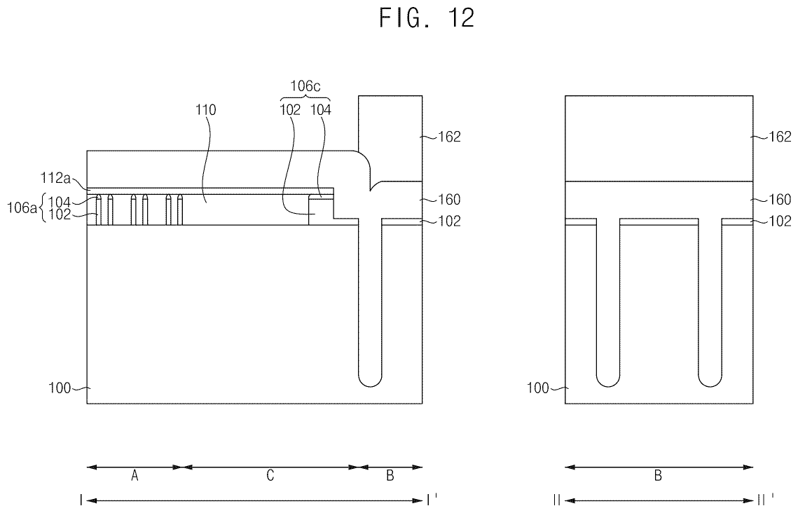

Referring to FIG. 12, a second photoresist pattern 162 may be formed to cover the protective layer 160 on the core/peripheral region B. The protective layer 160 on the cell region A and the boundary region C may be selectively exposed by the second photoresist pattern 162.

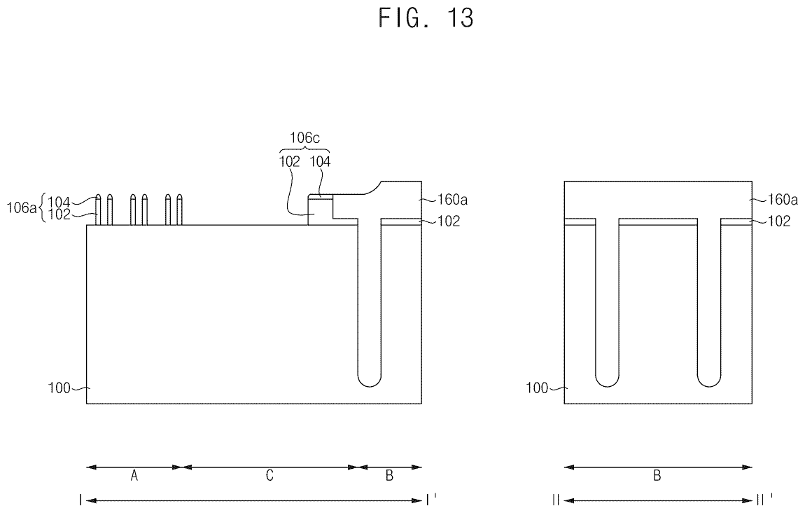

Referring to FIG. 13, the protective layer 160 and the second mask pattern 112a on the cell region A and the boundary region C may be removed by using the second photoresist pattern 162 as an etching mask. Accordingly, a protective layer pattern 160a may be formed on remaining the silicon oxide layer pattern 102 on the core/peripheral region B.

In the removing process, an upper surface of the polysilicon pattern 104 included in each of the first mask pattern structure 106a and the third mask pattern structure 106c may be used as an etching mask. In example embodiments, the protective layer 160 having a thick thickness in the vertical direction at the edge of the core/peripheral region B may be additionally etched by the removing process.

When the protective layer 160 and the second mask pattern 112a are formed of, e.g., silicon oxide, the protective layer 160 and the second mask pattern 112a on the cell region A and the boundary region C may be removed by the same etching process.

Thereafter, the second photoresist pattern 162 and the first mask pattern 110 may be removed. The removing process of the second photoresist pattern 162 and the first mask pattern 110 may include an ashing process and a stripping process.

When the processes are performed, the first mask pattern structures 106a and the third mask pattern structures 106c may remain on the cell region A and the boundary region C. The substrate 100 may be exposed between the first mask pattern structures 106a and between the first mask pattern structure 106a and the third mask pattern structure 106c.

In addition, a protective layer pattern 160a may be formed on the core/peripheral region B to fill the second trench 122, and the protective layer pattern 160a may cover the substrate 100 of the core/peripheral region B. An entire of the substrate 100 of the core/peripheral region B may be covered by the protective layer pattern 160a.

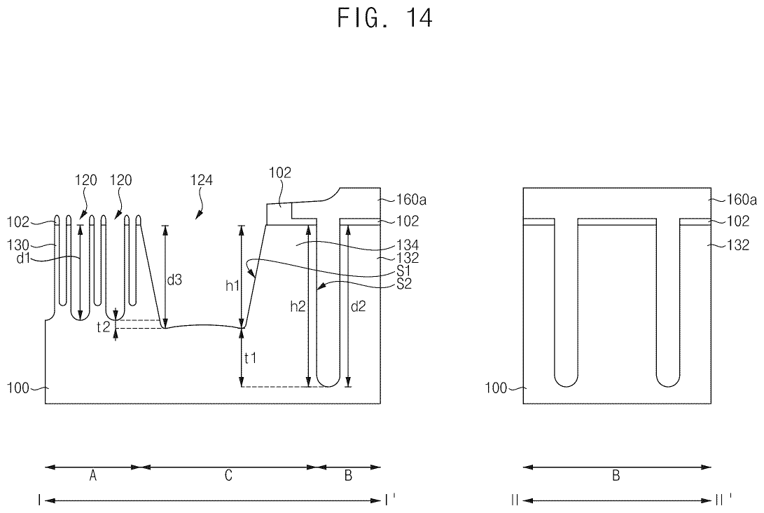

Referring to FIG. 14, the substrate 100 may be anisotropically etched using the first mask pattern structures 106a, the third mask pattern structure 106c, and the protective layer pattern 160a as etching masks to form first trenches 120 at the substrate 100 of the cell region A and a boundary trench 124 at the substrate 100 of the boundary region C.

In the etching process (i.e., second etching process), the first mask pattern structures 106a, the third mask pattern structure 106c, and the protective layer pattern 160a may not be completely removed, but may be partially removed. In example embodiments, after the second etching process is performed, the silicon oxide layer pattern 102 and the protective layer pattern 160a included in each of the first mask pattern structure 106a and the third mask pattern structure 106c may remain on the substrate 100 to a certain thickness.

A region of the substrate 100 in which the first trench 120 is not formed in the substrate 100 of the cell region A may serve as a first active pattern 130. A region of the substrate 100 in which the boundary trench 124 is not formed in the substrate 100 of the boundary region C may serve as an active dam pattern 134.

In example embodiments, the active dam pattern 134 may be adjacent to the core/peripheral region B, and the core/peripheral region B and the boundary region C may be distinguished by the active dam pattern 134. The active dam pattern 134 may be disposed between the boundary trench 124 and the second trench 122.

In example embodiments, the active dam pattern 134 may have a line shape extending in one direction. The active dam pattern 134 may extend, e.g., in the first direction X or the second direction Y.

The first trench 120 and the boundary trench 124 may be formed by the second etching process. Since the second trench 122 is already formed by the first etching process, the second etching process may be performed under process conditions that only consider the forming of the first trench 120 and the boundary trench 124 without considering the forming of the second trench 122. In the second etching process, the process condition may be controlled to form a target first trench 120 and a target boundary trench 124. For example, the first active pattern 130 between the first trenches 120 may be formed to have a target sidewall profile.

The first trench 120 can have a target inner width and a target depth. In addition, the boundary trench 124 can have a target inner width and a target depth.

The inner width of the boundary trench 124 may be greater than the inner widths of the first and second trenches 120 and 122. The inner width of the second trench 122 may be greater than the inner width of the first trench 120.

The first trench 120 may have a first depth d1, and the boundary trench 124 may have a third depth d3. Each of the first depth d1 and the third depth d3 may be less than the second depth d2 of the second trench 122.

In example embodiments, since the inner width of the boundary trench 124 is greater than the inner width of the first trench 120, the third depth d3 may be greater than the first depth d1. In some example embodiments, the third depth d3 may be the same as or similar to the first depth d1. A difference t1 between the second depth d2 and the third depth d3 may be greater than a difference t2 between the first depth d1 and the third depth d3. In example embodiments, the second depth d2 may be greater than the third depth d3 by at least 500 Å. For example, the second depth d2 may be greater than the third depth d3 by at least 1000 Å.

A sidewall of the first trench 120 may extend substantially in the vertical direction with respect to the bottom surface of the substrate 100. A sidewall of the boundary trench 124 may have a slope other than vertical. The sidewall of the boundary trench 124 may have a slope so that the inner width decreases from the top to the bottom of the boundary trench 124.

The sidewall of the first trench 120 may have a first slope, and the sidewall of the boundary trench 124 may have a third slope. The sidewall of the second trench 122 may have a second slope. The first slope and the third slope may be different from each other. The second slope and the third slope may be different from each other.

Both sidewalls of the active dam pattern 134 may be defined as one sidewall of the boundary trench 124 and one sidewall of the second trench 122, respectively. A first sidewall S1 of the active dam pattern 134 may correspond to one sidewall of the boundary trench 124, and a second sidewall S2 of the active dam pattern 134 facing the first sidewall S1 may correspond to one sidewall of the second trench 122.

The first sidewall S1 of the active dam pattern 134 may have the third slope, and the second sidewall S2 of the active dam pattern 134 may have the second slope. The sidewalls of the active dam pattern 134 facing each other may have different slopes with respect to a bottom surface of the substrate 100. In the active dam pattern 134, the second slope may be steeper than the third slope.

In addition, a height h1 of the first sidewall S1 of the active dam pattern 134 may be different from a height h2 of the second sidewall S2 of the active dam pattern 134. The height h1 of the first sidewall S1 of the active dam pattern 134 may be lower than the height h2 of the second sidewall S2 of the active dam pattern 134.

A bottom surface of the first trench 120 may have a shape that is rounded downward. In example embodiments, a bottom surface of the boundary trench 124 may have a shape that is rounded upward. A central portion of the bottom surface of the boundary trench 124 may have a shape that is convex upward compared to an edge portion of the bottom surface of the boundary trench 124.

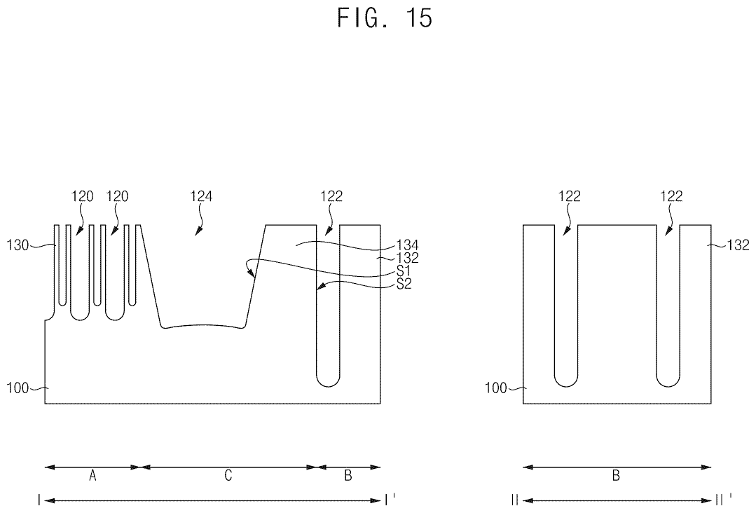

Referring to FIGS. 15 and 16, remaining silicon oxide layer pattern 102 and the protective layer pattern 160a may be removed. The removing process may include, e.g., a wet etching process.

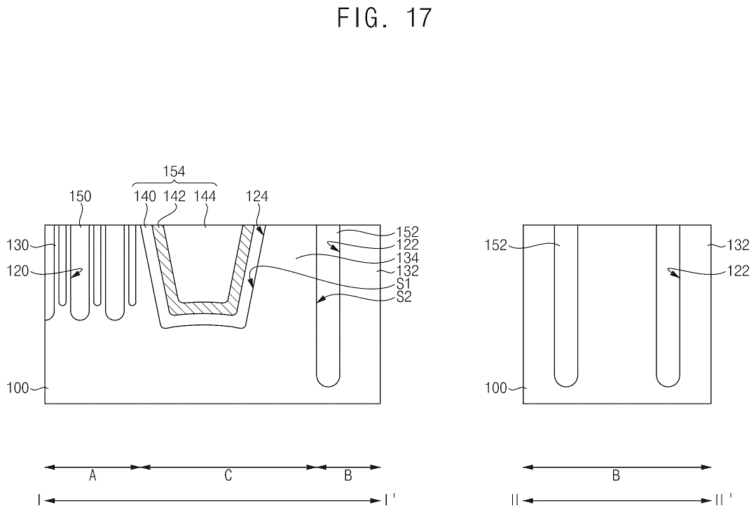

Referring to FIG. 17, a first device isolation pattern 150 may be formed in the first trench 120. A second device isolation pattern 152 may be formed in the second trench 122. A third device isolation pattern 154 may be formed in the boundary trench 124.

Particularly, a first insulation layer may be formed on the upper surface of the substrate 100 and in the first trench 120, the boundary trench 124, and the second trench 122. The first insulation layer may be formed to completely fill the first trench 120 and the second trench 122. The first insulation layer may be formed along the sidewall and the bottom of the boundary trench 124.

A second insulation layer may be formed on the first insulation layer. The second insulation layer may be formed along the sidewall and the bottom of the boundary trench 124. A third insulation layer may be formed on the second insulation layer. The third insulation layer may be formed to completely fill the boundary trench 124.

The first and third insulation layers may include, e.g., silicon oxide. The second insulation layer may include, e.g., silicon nitride.

Thereafter, the first to third insulation layers may be planarized until the upper surface of the substrate 100 is exposed, so that a first device isolation pattern 150 in the first trench 120, a second device isolation pattern 152 in the second trench 122, and a third device isolation pattern 154 in the boundary trench 124 may be formed. The first and second device isolation patterns 150 and 152 may include a first insulation layer pattern. The third device isolation pattern 154 may include the first insulation layer pattern 140, a second insulation layer pattern 142, and a third insulation layer pattern 144 sequentially stacked on the surface of the boundary trench 124. However, a stacked structure of the insulation layer patterns included in the first to third device isolation patterns 150, 152, and 154 may not be limited thereto.

According to the above processes, the first to third mask pattern structures 106a, 106b, and 106c (referred to FIG. 4) used as etching masks for forming the first trench 120, the second trench 122, and the boundary trench 124 may be formed together. Thereafter, the first etching process for forming the second trench 122 may be performed. After forming the second trench 122, the second etching process for forming the first trench 120 and the boundary trench 124 is performed.

Therefore, in the first etching process for forming the second trench 122, the process conditions may be adjusted without considering of the forming of the first trench 120 and the boundary trench 124. Therefore, the first etching process may be processed so that the upper inner width of the second trench 122 is hardly expanded, and thus the second active pattern 132 may have a sufficient upper surface area. The second trench 122 may be formed to have a target depth. The second trench 122 may be deeper than the first trench 120 and the boundary trench 124. The second trench 122 may be formed to have a sufficient depth so that a device isolation characteristic may be improved.

In addition, in the second etching process for forming the first trench 120 and the boundary trench 124, the process conditions may be adjusted without considering of forming of the second trench 122. For example, the first trench 120 and the boundary trench 124 may be formed independently of the second trench 122. Therefore, the first active pattern 130 formed by the first trench 120 may have a structure suitable for forming target memory cells.

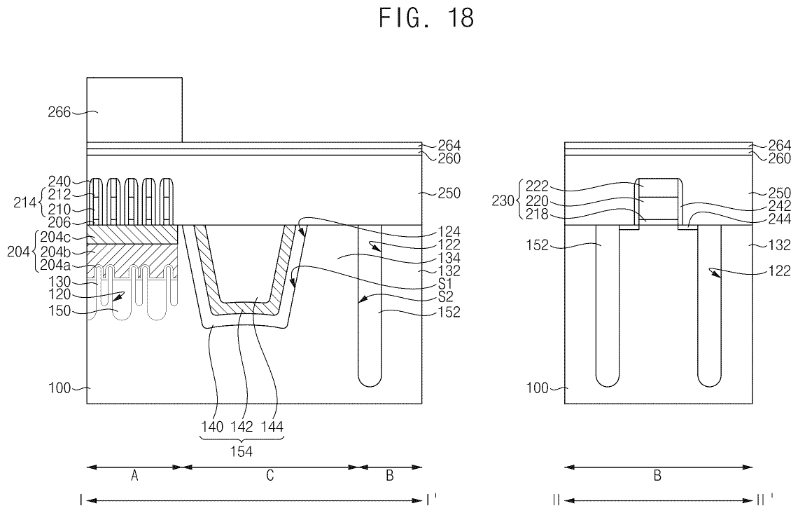

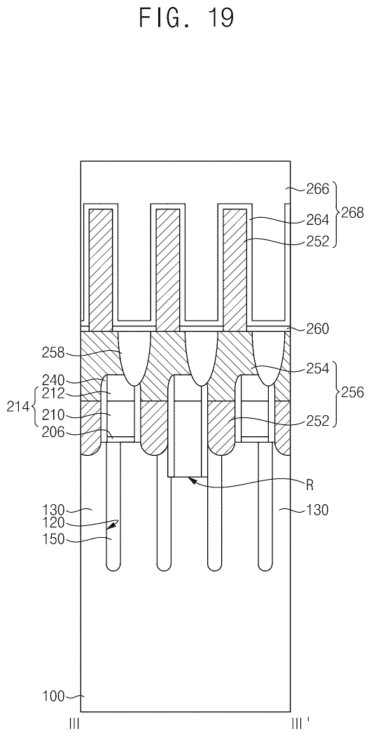

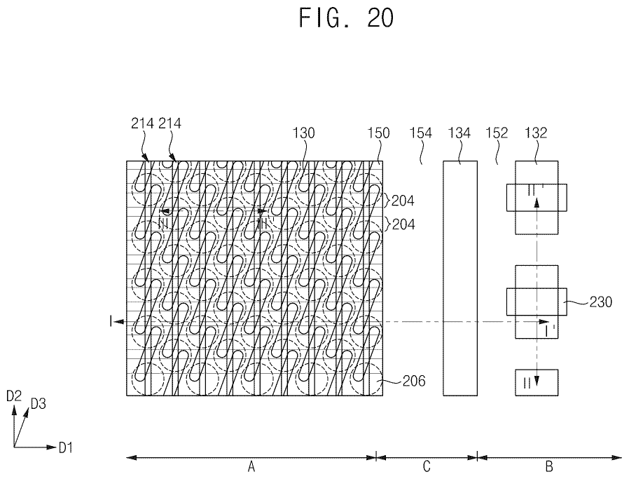

FIGS. 18 and 19 are cross-sectional views illustrating semiconductor devices according to example embodiments. FIG. 20 is a plan view illustrating semiconductor devices according to example embodiments.

The semiconductor devices illustrated in FIGS. 18 to 20 may be DRAM devices. FIG. 18 includes cross-sectional views taken along lines I-I′ and II-II′ of FIG. 20. FIG. 19 is a cross-sectional view taken along line III-III′ of FIG. 20. To avoid complexity of the drawing, some components, e.g., capacitors are omitted in FIG. 20.

Referring to FIGS. 18 to 20, the first trench 120 may be provided at the substrate 100 of the cell region A. The first active patterns 130 may be disposed between first trenches 120 of the cell region A. The first device isolation pattern 150 may fill the first trench 120.

The second trench 122 may be provided at the substrate 100 of the core/peripheral region B, and the second device isolation pattern 152 may fill the second trench 122. In the core/peripheral region B, a region of the substrate 100 where the second device isolation pattern 152 is not formed may serve as the second active pattern 132. An upper surface of the second active pattern 132 may serve as an active region.

The boundary trench 124 may be provided at the substrate 100 of the boundary region C, and the third device isolation pattern 154 may fill the boundary trench 124. In the boundary region C, the active dam pattern 134 may be disposed outside the boundary trench 124. The active dam pattern 134 may be disposed between the boundary trench 124 and the second trench 122.

The first and second trenches 120, 122 and the boundary trench 124 may be the same as those described with reference to FIGS. 1 to 4, respectively. The first active pattern 130, the second active pattern 132, and the active dam pattern 134 may be the same as those described with reference to FIGS. 1 to 4, respectively. The first device isolation pattern 150, the second device isolation pattern 152, and the third device isolation pattern 154 may be the same as those described with reference to FIGS. 1 to 4, respectively.

Memory cells may be formed on the substrate 100 of the cell region A. The memory cell may include a cell selection transistor, a bit line structure 214, and a capacitor 268. A unit memory cell may include one cell selection transistor and one capacitor 268. In addition, a contact structure 256, an upper insulation pattern 258, a first interlayer insulation layer 250, and an etch stop layer 260 may be further included on the substrate 100 of the cell region A.

A gate trench extending in the first direction D1 may be provided at the substrate 100 of the cell region A. A first gate structure 204 may be in the gate trench. The first gate structure 204 may be a buried gate having a form buried in the substrate 100. The first gate structure 204 may serve as a word line.

In example embodiments, the first gate structure 204 may include a first gate insulation layer 204a, a first gate electrode 204b, and a first capping insulation pattern 204c. The first gate structure 204 may extend in the first direction D1. A plurality of first gate structures 204 may be spaced apart from each other in the second direction D2.

Impurity regions serving as source/drain regions may be at upper portions of the first active pattern 130 between the first gate structures 204. For example, a first impurity region electrically connected to the bit line structure 214 and a second impurity region electrically connected to the capacitor 268 may be provided at the upper portions of the first active pattern 130. The first gate structure 204 and the first and second impurity regions may be provided as the cell selection transistor.

An insulation pattern 206 may be formed on the first active pattern 130, the first device isolation pattern 150, and the first gate structure 204.

A portion of the substrate 100 where the insulation pattern 206 is not formed may have a recessed shape. An upper surface of the first impurity region may be exposed by the lower surface of a recessed portion R.

The bit line structure 214 may be formed on the recessed portion R and the insulation pattern 206. The bit line structure 214 may include a first conductive pattern 210 and a first hard mask pattern 212. For example, the first conductive pattern 210 may have a structure in which a polysilicon pattern, a barrier metal pattern, and a metal pattern are sequentially stacked.

The bit line structure 214 may extend in the second direction D2. A plurality of bit line structures 214 may be spaced apart from each other in the first direction D1. In example embodiments, a first spacer 240 may be on sidewalls of the bit line structure 214. In some example embodiments, the first spacer 240 may have a structure in which a plurality of spacers is laterally stacked.

The first interlayer insulation layer 250 may fill a space between the bit line structures 214, and may cover the bit line structures 214.

The contact structure 256 may pass through the first interlayer insulation layer 250 and the insulation pattern 206 on the cell region A, and may contact the second impurity region. The contact structure 256 may have a contact plug 252 and a landing pad 254 stacked. The contact plug 252 may be disposed between the bit line structures 214. The landing pad 254 may be formed on the contact plug 252. The upper insulation pattern 258 may be disposed between the landing pads 254.

The etch stop layer 260 may be disposed on the landing pad 254, the upper insulation pattern 258, and the first interlayer insulation layer 250. The capacitor 268 may pass through the etch stop layer 260, and may contact the landing pad 254.

The etch stop layer 260 may include, e.g., silicon nitride, silicon oxynitride, etc.

The capacitor 268 may include a lower electrode 262, a dielectric layer 264, and an upper electrode 266. A bottom of the lower electrode 262 may contact the landing pad 254. Therefore, the capacitor 268 may be electrically connected to the second impurity region. A second gate structure 230 may be on the second active pattern 132 in the core/peripheral region B. The second gate structure 230 may have a stacked structure including a second gate insulation layer pattern 218, a second conductive pattern 220, and a second hard mask pattern 222. A second spacer 242 may be on sidewalls of the second gate structure 230.

In example embodiments, a stacked structure of the first conductive pattern 210 and the first hard mask pattern 212 included in the bit line structure 214 and a stacked structure of the second conductive pattern 220 and the second hard mask pattern 222 included the second gate structure 230 may be the same as each other.

Third impurity regions 244 serving as source/drain regions may be formed at upper portions of the second active pattern 132 adjacent to sidewalls of the second gate structure 230.

Since the second active pattern 132 in the core/peripheral region B has a sufficient upper surface area, the core/peripheral transistor formed on the second active pattern 132 in the core/peripheral region B may have excellent electrical characteristics.

Circuit patterns may not be disposed on the active dam pattern 134 in the boundary region C. For example, transistors may not be disposed on the active dam pattern 134.

The first interlayer insulation layer 250 may cover the substrate 100 of the boundary region C and the core/peripheral region B and the second gate structure 230.

The etch stop layer 260 and the dielectric layer 264 may be stacked on the first interlayer insulation layer 250 in the boundary region C and the core/peripheral region B.

As described above, patterns constituting a semiconductor device may be disposed on the first to third active patterns 130, 132, 134 and the device isolation patterns 150, 152, and 154 at the substrate 100 of the cell region A, the core/peripheral region B, and the boundary region C. The memory cells may be disposed on the first active pattern 130 in the cell region A. Core/peripheral transistors may be disposed on the core/peripheral region B. Since the second active pattern 132 on the core/peripheral region B has a sufficient upper surface area, core/peripheral circuits disposed on the core/peripheral region B may have excellent electrical characteristics.

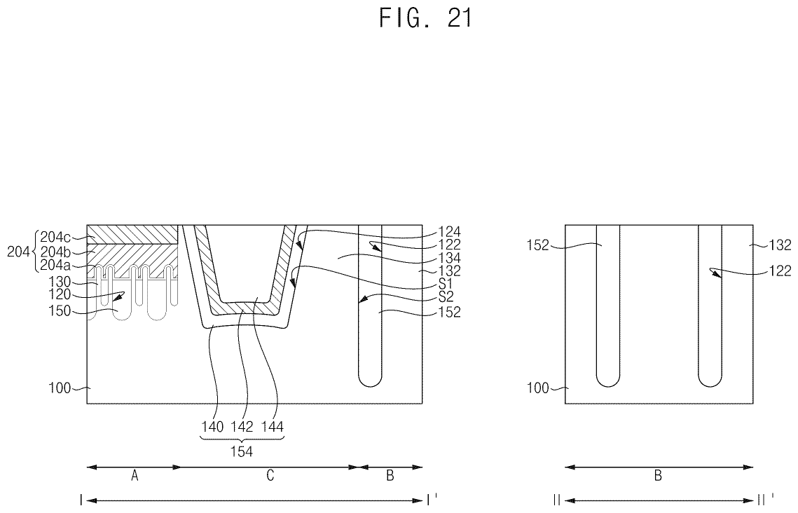

FIGS. 21 to 30 are cross-sectional views and plan views illustrating a method of manufacturing a semiconductor device according to example embodiments.

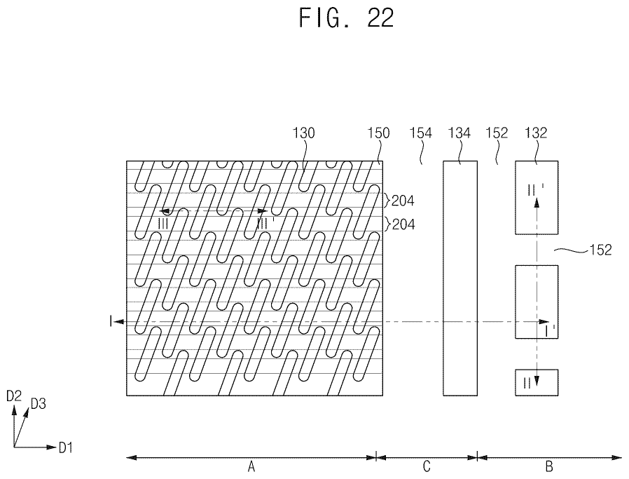

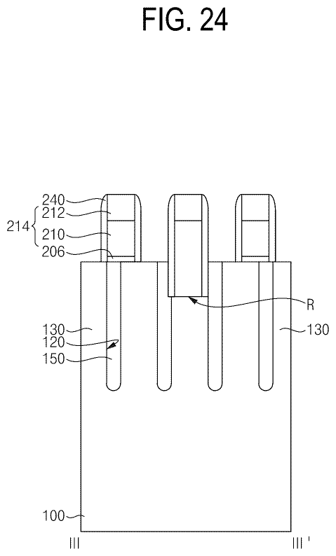

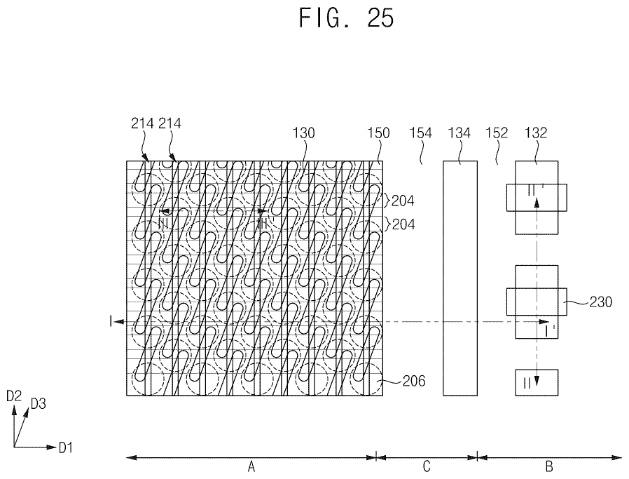

FIGS. 21, 23, 26, and 28 include cross-sectional views taken along lines I-I′ and II-II′ of the plan view. FIGS. 24, 27, and 29 include cross-sectional views taken along lines III-III′ of the plan view. FIGS. 22 and 25 are plan views.

Referring to FIGS. 21 and 22, first, the processes described with reference to FIGS. 4 to 17 may be performed to form the structures illustrated in FIG. 17.

Upper portions of the first active pattern 130 and the first device isolation pattern 150 in the cell region A may be etched to form a gate trench 202 extending in the first direction D1. A first gate structure 204 may be formed in the gate trench 202. The first gate structure 204 may include a first gate insulation layer 204a, a first gate electrode 204b, and a first capping insulation pattern 204c.

N-type impurities may be doped at the upper portion of the first active pattern 130 adjacent to both sides of the first gate structure 204 to form first and second impurity regions. Therefore, a cell selection transistor including the gate structure and the first and second impurity regions may be formed. The cell selection transistor may be a recessed channel transistor. The first and second impurity regions may serve as source/drain regions of the cell selection transistor.

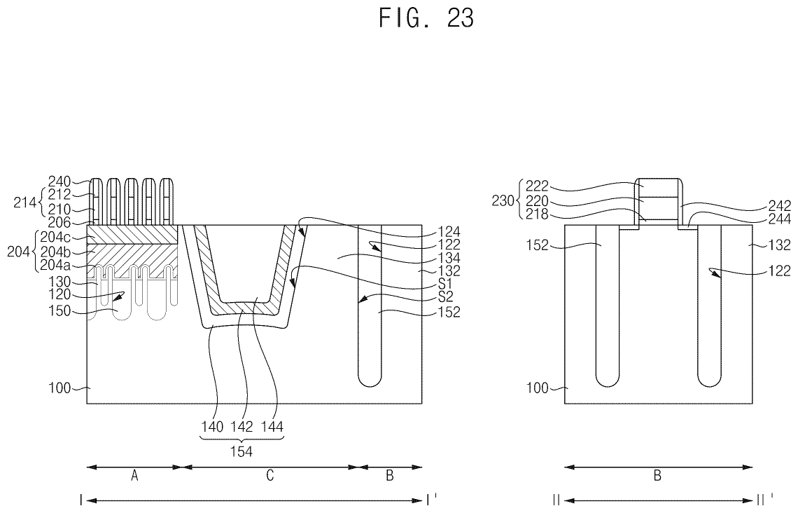

Referring to FIGS. 23 to 25, an insulation pattern 206 may be formed on the substrate 100, the first to third device isolation patterns 150, 152, and 154, and the first gate structure 204. A region of the substrates 100 where the insulation pattern 206 is not formed may include a recess R. An upper surface of the first impurity region may be exposed by the bottom of the recess R.

A bit line structure 214 extending in the second direction D2 may be formed on the insulation pattern 206 and the recess R in the cell region A. The bit line structure 214 may be electrically connected to the first impurity region. In addition, in the process of forming the bit line structure 214, a second gate structure 230 having a planar-type may be formed on the substrate 100 of the core/peripheral region B together.

In example embodiments, the bit line structure 214 may have a stacked structure including a first conductive pattern 210 and a first hard mask pattern 212. In example embodiments, the second gate structure 230 may have a stacked structure including a second gate insulation layer pattern 218, a second conductive pattern 220, and a second hard mask pattern 222.

A first spacer 240 may be formed on sidewalls of the bit line structure 214. A second spacer 242 may be formed on sidewalls of the second gate structure 230.

Third impurity regions 244 may be formed at the substrate 100 of the core/peripheral region B adjacent to both sides of the second gate structure 230.

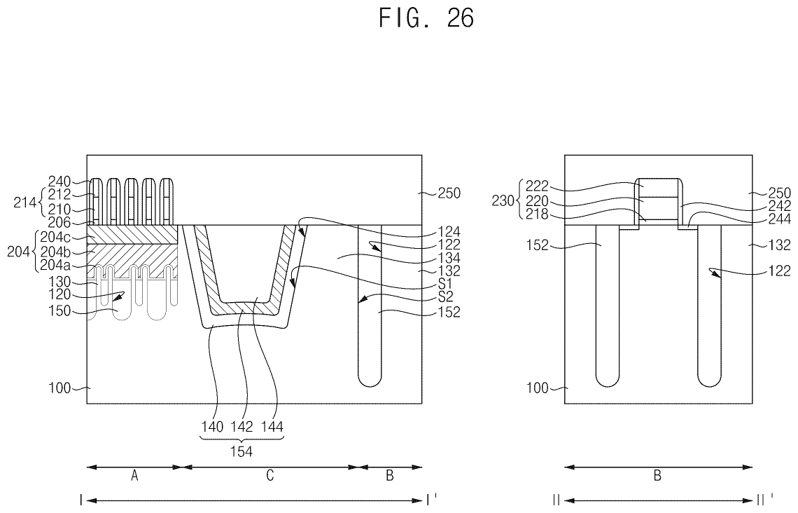

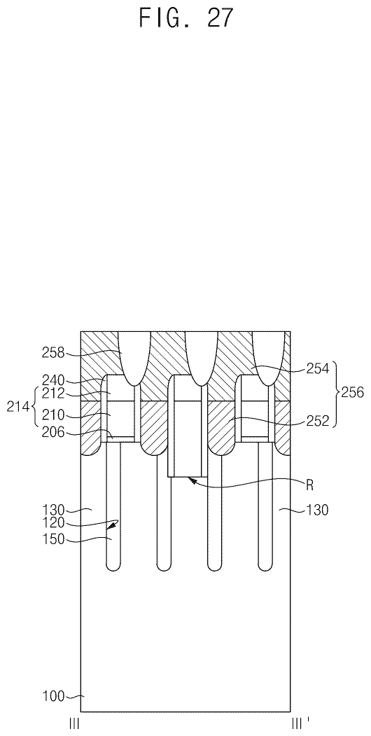

Referring to FIGS. 26 and 27, a first interlayer insulation layer 250 may be formed to cover the bit line structures 214 and the second gate structure 230.

A portion of the first interlayer insulation layer 250 between the bit line structures 214A may be etched to form a contact hole exposing the second impurity region of the substrate 100. A contact structure 256 in which a contact plug 252 and a landing pad 254 are stacked may be formed in the contact hole.

The contact plug 252 may be formed on the bottom of the contact hole, and the landing pad 254 may be formed on the contact plug 252 at an upper portion of the contact hole. An upper insulation pattern 258 may be formed between the landing pads 254.

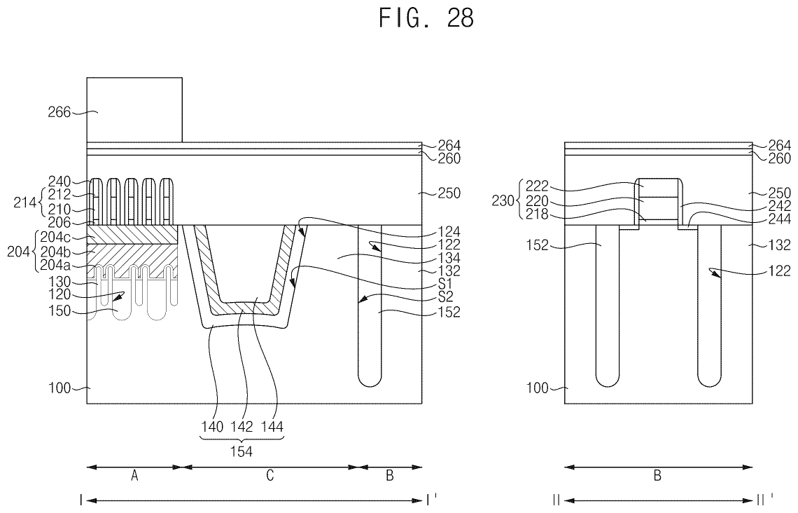

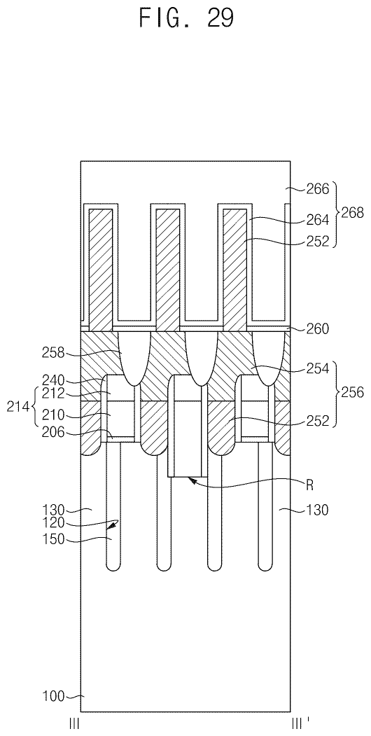

Referring to FIGS. 28 and 29, an etch stop layer 260 may be formed on the first interlayer insulation layer 250, the landing pad 254, and the upper insulation pattern 258. The etch stop layer 260 may include, e.g., silicon nitride, silicon oxynitride, etc.

A lower electrode 262 may be formed so that the lower electrode 262 may pass through the etch stop layer 260. The lower electrode 262 may contact an upper surface of the landing pad 254. The lower electrode 262 may be positioned at each of vertices and a center of a hexagon, so that a plurality of the electrodes 262 may be arranged in a honeycomb structure. A dielectric layer 264 may be formed on surfaces of the lower electrode 262 and the etch stop layer 260. The dielectric layer 264 may include a metal oxide having a high dielectric constant. For example, the dielectric layer 264 may include HfO₂, ZrO₂, TiO₂, TaO, or La₂O₃.

An upper electrode 266 may be formed on the dielectric layer 264. Accordingly, a capacitor 268 including the lower electrode 262, the dielectric layer 264, and the upper electrode 266 may be formed. The capacitor 268 may be electrically connected to the second impurity region.

By the above process, a DRAM device may be manufactured.

While the present inventive concepts have been shown and described with reference to example embodiments thereof, it will be understood by those of ordinary skill in the art that various changes in form and details may be made thereto without departing from the scope of the present inventive concepts as set forth by the following claims.

What is claimed is:

1. A semiconductor device, comprising:
a substrate including a first trench in a cell region, a second trench in a core/peripheral region, and a boundary trench in a boundary region between the cell region and the core/peripheral region, and the substrate including an active dam pattern between the boundary trench and the second trench;
a first device isolation pattern filling the first trench;
a second device isolation pattern filling the second trench; and
a third device isolation pattern filling the boundary trench,
wherein a first sidewall of the active dam pattern corresponding to one sidewall of the boundary trench and a second sidewall of the active dam pattern corresponding to one sidewall of the second trench face each other, and
wherein a slope of the first sidewall is different from a slope of the second sidewall with respect to a bottom surface of the substrate.

2. The semiconductor device of claim 1, wherein the slope of the second sidewall of the active dam pattern is steeper than the slope of the first sidewall of the active dam pattern.

3. The semiconductor device of claim 2, wherein the slope of the second sidewall of the active dam pattern is vertical.

4. The semiconductor device in claim 1, wherein a difference between an inner width at an uppermost portion of the second trench and an inner width at a middle portion of the second trench in a vertical direction perpendicular to the bottom surface of the substrate is less than 5% of the inner width at the uppermost portion of the second trench.

5. The semiconductor device in claim 1, wherein inner widths of the second trench are the same at each of positions in a vertical direction perpendicular to the bottom surface of the substrate.

6. The semiconductor device of claim 1, wherein a vertical distance from a top to a bottom of the first sidewall of the active dam pattern is less than the vertical distance from a top to a bottom of the second sidewall of the active dam pattern.

7. The semiconductor device of claim 1,
wherein a sidewall of the first trench has a first slope with respect to the bottom surface of the substrate, the sidewall of the second trench has a second slope with respect to the bottom surface of the substrate, and the sidewall of the boundary trench has a third slope with respect to the bottom surface of the substrate, and
wherein the first slope is different from the third slope.

8. The semiconductor device of claim 1, wherein a bottom of the second trench is lower than a bottom of the boundary trench and a bottom of the first trench.

9. The semiconductor device of claim 1,
wherein the first trench has a first depth, the second trench has a second depth, the boundary trench has a third depth, and
wherein the second depth is greater than each of the first depth and the third depth.

10. The semiconductor device of claim 9, wherein a difference between the second depth and the third depth is greater than a difference between the first depth and the third depth.

11. The semiconductor device of claim 9, wherein the second depth is greater than the third depth by at least 500 Å.

12. A semiconductor device, comprising:
a substrate including a first trench and a first active pattern in a cell region, a second trench and a second active pattern in a core/peripheral region, and a boundary trench and an active dam pattern in a boundary region between the cell region and the core/peripheral region;
a first device isolation pattern filling the first trench;
a second device isolation pattern filling the second trench; and
a third device isolation pattern filling the boundary trench,
wherein the active dam pattern is positioned between the boundary trench and the second trench, and a first sidewall of the active dam pattern and a second sidewall facing the first sidewall of the active dam pattern are asymmetrical to each other, and
wherein the second trench has a depth greater than a depth of the boundary trench.

13. The semiconductor device of claim 12,
wherein the first sidewall of the active dam pattern corresponds to one sidewall of the boundary trench, the second sidewall of the active dam pattern corresponds to one sidewall of the second trench, and
wherein a slope of the second sidewall of the active dam pattern is steeper than a slope of the first sidewall of the active dam pattern.

14. The semiconductor device of claim 12, wherein a difference between an inner width at a top of the second trench and an inner width at a middle portion of the second trench in a vertical direction perpendicular to an upper surface of the substrate is less than 5% of the inner width at the top of the second trench.

15. The semiconductor device of claim 12, wherein inner widths of the second trench are the same at each of positions in a vertical direction perpendicular to a bottom surface of the substrate.

16. The semiconductor device of claim 12,
wherein the first trench has a first depth, the second trench has a second depth, the boundary trench has a third depth, and
wherein a difference between the second depth and the third depth is greater than a difference between the first depth and the third depth.

17. A semiconductor device, comprising:
a substrate including a first trench and a first active pattern in a cell region, a second trench and a second active pattern in a core/peripheral region, and a boundary trench and an active dam pattern in a boundary region between the cell region and the core/peripheral region;
a first device isolation pattern filling the first trench;
a second device isolation pattern filling the second trench;
a third device isolation pattern filling the boundary trench;
a first gate structure buried in the substrate of the cell region, the first gate structure extending in a first direction;
a bit line structure on the substrate of the cell region;
a capacitor on the substrate of the cell region; and
a core/peripheral transistor on the second active pattern in the substrate of the core/peripheral region,
wherein the first trench has a first depth, the second trench has a second depth, and the boundary trench has a third depth, and
wherein a difference between the second depth and the third depth is greater than a difference between the first depth and the third depth.

18. The semiconductor device of claim 17,
wherein the active dam pattern is disposed between the boundary trench and the second trench, and
wherein a first sidewall of the active dam pattern and a second sidewall facing the first sidewall are asymmetrical to each other.

19. The semiconductor device of claim 17,
wherein a first sidewall of the active dam pattern corresponds to one sidewall of the boundary trench, and a second sidewall of the active dam pattern corresponds to one sidewall of the second trench, and
wherein a slope of the second sidewall of the active dam pattern is steeper than the slope of the first sidewall of the active dam pattern.

20. The semiconductor device of claim 17, wherein a difference between an inner width at an uppermost portion of the second trench and the inner width at a middle portion of the second trench in a vertical direction perpendicular to a bottom surface of the substrate is less than 5% of the inner width at the uppermost portion of the second trench.
